(19) United States
(12) Patent Application Publication
(10) Pub. No.: US 2025/0046656 A1
(43) Pub. Date: Feb. 6, 2025

(54) SEMICONDUCTOR DEVICE AND METHOD OF MANUFACTURING SAME

(71) Applicant: SOCPRA SCIENCES ET GENIE S.E.C., Sherbrooke (CA)

(72) Inventors: Thierno Mamoudou DIALLO, Pierrefonds (CA); Abderraouf BOUCHERIF, Sherbrooke (CA); Tadeáš HANUŠ, Sherbrooke (CA)

(21) Appl. No.: 18/789,879

(22) Filed: Jul. 31, 2024

(30) Foreign Application Priority Data
Aug. 3, 2023 (CA) 3208369

(51) Int. Cl. H01L 21/78; C30B 25/04; C30B 29/06; C30B 29/08; C30B 33/12; H01L 21/02

(52) U.S. Cl. CPC H01L 21/7813; C30B 25/04; C30B 29/06; C30B 29/08; C30B 33/12; H01L 21/02444; H01L 21/02513; H01L 21/02532; H01L 21/02598; H01L 21/02642

(57) ABSTRACT

There is described a method of manufacturing a semiconductor device. The method generally has the steps of: depositing graphene on a monocrystalline semiconductor substrate, the graphene having an opening exposing the monocrystalline semiconductor substrate through the graphene; and growing a given monocrystalline semiconductor material from the monocrystalline semiconductor substrate through the opening, said growing including the given monocrystalline semiconductor material outgrowing the opening and covering the graphene thereby forming a monocrystalline semiconductor layer on the graphene.

### FIELD

The improvements generally relate to semiconductor devices and more specifically to substrates of such semiconductor devices.

### BACKGROUND

A semiconductor device generally has one or more components grown on a semiconductor substrate. The semiconductor substrate is typically provided in the form of a bulky wafer of costly monocrystalline semiconductor material which has an exposed surface being defect-free to favour successful growth of the components thereon. As the component growth requires only a shallow portion of the semiconductor substrate, techniques have been developed to harness the full potential of these bulky wafers. For instance, some techniques involve the weakening of an upper layer of the semiconductor substrate and the formation of an epilayer of monocrystalline semiconductor material atop the weakened upper layer. In these techniques, once the components have been grown onto the epilayer, the underneath weakened layer can be broken off or otherwise detached from the remainder of the semiconductor substrate. Once detached, the separate pieces consist of a standalone semiconductor device, and a remaining semiconductor substrate portion which can be re-used for another iteration of the same method after an appropriate surface treatment step. In this way, a bulky wafer of costly monocrystalline semiconductor material can be re-used iteratively to manufacture more than one semiconductor device. Although existing semiconductor substrate re-use techniques have been satisfactory to a certain degree, there remains room for improvement.

### SUMMARY

As two-dimensional (2D) layered materials such as graphene have been found to exhibit unique physical properties, the inventors have proposed graphene as an intermediate layer sandwiched between the semiconductor substrate and the epilayer of monocrystalline semiconductor material. It was hypothesised that the graphene layer could be broken off to separate the semiconductor substrate from the epilayer and thereby allow the semiconductor substrate to be re-used. In practice, growing monocrystalline semiconductor material such as the epilayer on graphene was found to be challenging due to the graphene's low surface energy which typically only allows undesirable polycrystalline semiconductor growth. In some specific situations, for instance when the semiconductor substrate is made of a polar semiconductor material, Van der Waals epitaxy (VdWE) can be used to grow the epilayer of monocrystalline semiconductor material layer atop the graphene in a satisfactory way. However, even when epitaxial growth on the graphene is successful, challenges remain in breaking the graphene to allow the detachment of the epilayer from the semiconductor substrate.

This disclosure describes a method of manufacturing a semiconductor device which alleviate at least some of the aforementioned challenges. More specifically, the method includes a step of depositing graphene on a monocrystalline semiconductor substrate. The graphene has opening(s) exposing the monocrystalline semiconductor substrate through the graphene. The opening(s) can be made by removing carbon atoms at one or more locations using for instance a high-energy beam such as a plasma beam (e.g., an oxygen-plasma beam, an electron beam) or by simply performing only a partial graphene deposition onto the semiconductor substrate. The method includes another step of growing a given monocrystalline semiconductor material from the monocrystalline semiconductor substrate through the opening(s). This step of growing includes the given monocrystalline semiconductor material outgrowing the opening(s) and covering the graphene thereby forming a monocrystalline semiconductor layer, or epilayer, on the graphene. Now, it was found that since the epilayer growth is anchored directly onto the semiconductor substrate underneath the graphene via the opening(s), monocrystalline growth is favoured within the opening(s) but also across the whole surface of the graphene. Moreover, since the opening(s) are relatively small relative to the overall semiconductor device footprint, the crystalline structure(s) extending between the semiconductor substrate and the epilayer, within the opening(s), is (are) fragile enough to allow the detachment of the epilayer from the remainder of the semiconductor substrate. With the epilayer (which may or may not include components grown thereon) detached, the semiconductor substrate can be re-used for other iterations of the method after an appropriate surface treatment step.

In accordance with a first aspect of the present disclosure, there is provided a method of manufacturing a semiconductor device, the method comprising: depositing graphene on a monocrystalline semiconductor substrate, the graphene having an opening exposing the monocrystalline semiconductor substrate through the graphene; and growing a given monocrystalline semiconductor material from the monocrystalline semiconductor substrate through the opening, said growing including the given monocrystalline semiconductor material outgrowing the opening and covering the graphene thereby forming a monocrystalline semiconductor layer on the graphene.

Further in accordance with the first aspect of the present disclosure, said semiconductor device can for example have a monocrystalline structure extending between the monocrystalline semiconductor substrate and the monocrystalline semiconductor layer across the opening.

Still further in accordance with the first aspect of the present disclosure, said monocrystalline semiconductor substrate can for example be made of a non-polar monocrystalline semiconductor material.

Still further in accordance with the first aspect of the present disclosure, the non-polar monocrystalline semiconductor material can for example consist of one of: monocrystalline germanium and monocrystalline silicon.

Still further in accordance with the first aspect of the present disclosure, the monocrystalline semiconductor substrate can for example be made of the given monocrystalline semiconductor material.

Still further in accordance with the first aspect of the present disclosure, the given monocrystalline semiconductor material can for example be a first monocrystalline semiconductor material, the monocrystalline semiconductor substrate can for example be made of a second monocrystalline semiconductor material different from the first monocrystalline semiconductor material.

Still further in accordance with the first aspect of the present disclosure, the first monocrystalline semiconductor material can for example have a first crystalline lattice parameter matching a second crystalline lattice parameter of the second monocrystalline semiconductor material.

Still further in accordance with the first aspect of the present disclosure, the opening can for example have an in-plane dimension corresponding to one or more missing carbon atoms.

Still further in accordance with the first aspect of the present disclosure, the opening can for example have an in-plane dimension of at least 0.5 nm, preferably at least 1 nm and most preferably at least 5 nm. In some embodiments, the opening can for example have a maximal in-plane dimension of at most 150 nm, preferably at most 100 nm and most preferably at most 50 nm.

Still further in accordance with the first aspect of the present disclosure, said opening can for example have a plurality of openings at a corresponding plurality of spaced-apart locations of said graphene, said growing including growing the given monocrystalline semiconductor material from the monocrystalline semiconductor substrate through the plurality of openings at the plurality of spaced apart locations.

Still further in accordance with the first aspect of the present disclosure, the plurality of openings can for example have at least ten openings per unit of area, preferably more than a hundred openings per unit of area, and most preferably more than a thousand openings per unit of area.

Still further in accordance with the first aspect of the present disclosure, said depositing can for example include depositing a graphene layer on the monocrystalline semiconductor substrate, and removing a given portion of the graphene layer to form the opening.

Still further in accordance with the first aspect of the present disclosure, said removing can for example include projecting a plasma beam at a location of the given portion of the graphene layer, the plasma beam can for example carry an intensity value exceeding an opening forming intensity threshold.

Still further in accordance with the first aspect of the present disclosure, the plasma beam can for example be an oxygen-plasma beam.

Still further in accordance with the first aspect of the present disclosure, said depositing can for example include depositing graphene on a given portion of the monocrystalline semiconductor substrate, a remaining portion of the monocrystalline semiconductor substrate corresponding to the opening.

Still further in accordance with the first aspect of the present disclosure, said depositing can for example include positioning a growth mask onto the given portion of the monocrystalline semiconductor substrate, performing said depositing the graphene, and removing the growth mask thereby revealing the opening.

Still further in accordance with the first aspect of the present disclosure, the method can for example further comprise detaching the monocrystalline semiconductor layer from the monocrystalline semiconductor substrate.

In accordance with a second aspect of the present disclosure, there is provided a semiconductor device comprising: a monocrystalline semiconductor substrate; a graphene layer covering the monocrystalline semiconductor substrate, the graphene layer having an opening exposing the monocrystalline semiconductor substrate through the graphene layer; and a monocrystalline semiconductor layer having a first base portion anchoring to the monocrystalline semiconductor substrate via the opening, and a second sheet portion connected to the first base portion and covering the graphene layer.

Further in accordance with the second aspect of the present disclosure, said semiconductor device can for example have a monocrystalline structure extending between the monocrystalline semiconductor substrate and the monocrystalline semiconductor layer across the opening.

Still further in accordance with the second aspect of the present disclosure, said monocrystalline semiconductor substrate can for example be made of a non-polar monocrystalline semiconductor material.

All technical implementation details and advantages described with respect to a particular aspect of the present disclosure are self-evidently mutatis mutandis applicable for all other aspects of the present disclosure.

Many further features and combinations thereof concerning the present improvements will appear to those skilled in the art following a reading of the instant disclosure.

### DESCRIPTION OF THE FIGURES

In the figures,

FIG. 1A is a schematic side view of an example of a semiconductor substrate having graphene deposited thereon, in accordance with one or more embodiments;

FIG. 1B is a schematic side view of the semiconductor substrate of FIG. 1A, with openings formed within the graphene, in accordance with one or more embodiments;

FIG. 1C is a schematic side view of the semiconductor substrate of FIG. 1B, with monocrystalline semiconductor material growing from the semiconductor material via the openings, and outgrowing therefrom, in accordance with one or more embodiments;

FIG. 1D is a schematic side view of an example of a semiconductor device having the semiconductor substrate of FIG. 1C, and a monocrystalline semiconductor layer anchored to the semiconductor substrate via the openings and extending over the graphene, in accordance with one or more embodiments;

FIG. 1E is a schematic side view of the semiconductor device of FIG. 1D, with the monocrystalline semiconductor layer detached from the semiconductor substrate, in accordance with one or more embodiments;

FIG. 1F is a schematic side view of the semiconductor substrate of FIG. 1E after appropriate surface treatment steps, in accordance with one or more embodiments;

FIG. 2 is a flow chart of an example of a method of manufacturing a semiconductor device, in accordance with one or more embodiments;

FIG. 3 is a schematic view of an example system for manufacturing a semiconductor device, in accordance with one or more embodiments;

FIG. 4 is a schematic view of an example computing device of a controller of the system of FIG. 3, in accordance with one or more embodiments;

FIGS. 5A-5E include schematic views of a semiconductor device during its manufacture, showing plasma-induced openings formed into graphene, in accordance with one or more embodiments;

FIG. 6A is a graph showing a Raman spectra of a single layer graphene for different plasma treating durations, showing Raman features D, G and 2D, in accordance with one or more embodiments;

FIG. 6B is a graph showing an intensity ratio of the Raman features D and G as a function of different plasma treating durations, in accordance with one or more embodiments;

FIG. 6C is a graph showing a high-resolution x-ray photoelectron (XPS) intensity as a function of binding energy for different carbon bonds, in accordance with one or more embodiments;

FIG. 6D is a graph showing the C═C sp² bond area (decreasing curve) and sp³/sp² bond ratio (increasing curve) extracted from the XPS measurements of FIG. 6C for different plasma treating durations, in accordance with one or more embodiments;

FIG. 7A is a side elevation view of a given crystalline semiconductor material deposited onto graphene sitting atop a semiconductor substrate, with the graphene being defect-free, in accordance with one or more embodiments;

FIG. 7B is a side elevation view of a given crystalline semiconductor material deposited onto graphene sitting atop a semiconductor substrate, with the graphene showing dangling bonds, in accordance with one or more embodiments;

FIG. 7C is a side elevation view of a given crystalline semiconductor material deposited onto graphene sitting atop a semiconductor substrate, with the graphene having openings through which monocrystalline growth occurs, in accordance with one or more embodiments;

FIGS. 7D-F are scanning electron microscope (SEM) images of the substrate of FIG. 7C for a plasma treatment durations of 18 s, 24 s and 30 s, respectively, in accordance with one or more embodiments;

FIG. 7G is a graph showing surface coverage percentage as a function of plasma treatment duration, in accordance with one or more embodiments;

FIG. 8A is a low magnification plan-view SEM image showing a monocrystalline germanium layer deposited atop a plasma treated single layer graphene, in accordance with one or more embodiments;

FIG. 8B is a high magnification plan-view SEM image showing the monocrystalline germanium layer of FIG. 8A, in accordance with one or more embodiments;

FIG. 8C is an atomic force microscopy image of a 5×5 μm² area of the monocrystalline germanium layer of FIG. 8A, showing smooth surface with an RMS roughness of 2 nm, in accordance with one or more embodiments;

FIG. 8D is an electron backscatter diffraction (EBSD) map of the monocrystalline germanium layer of FIG. 8A, showing a monocrystalline nature, in accordance with one or more embodiments;

FIG. 9A is a transmission electron microscopy (TEM) image showing a cross-section of a germanium layer grown on a plasma treated single layer graphene sitting on a germanium substrate, in accordance with one or more embodiments;

FIG. 9B is a high-resolution TEM image of the cross-section of FIG. 9A, in accordance with one or more embodiments;

FIGS. 9C and 9D are fast Fourier transform (FFT) patterns of the germanium layer sitting atop the graphene and of the semiconductor substrate on which sits the graphene, respectively, with arrows pointing to the Ge (220) planes, in accordance with one or more embodiments;

FIGS. 9E and 9F are inverse FFT patterns of the Ge (220) planes of the germanium layer and the semiconductor substrate of FIG. 9A, in accordance with one or more embodiments; and

FIGS. 9G to 9J are geometrical phase analysis (GPA) deformation maps of the germanium layers grown onto the plasma treated graphene layer, taken from the image of FIG. 9B, in accordance with one or more embodiments.

### DETAILED DESCRIPTION

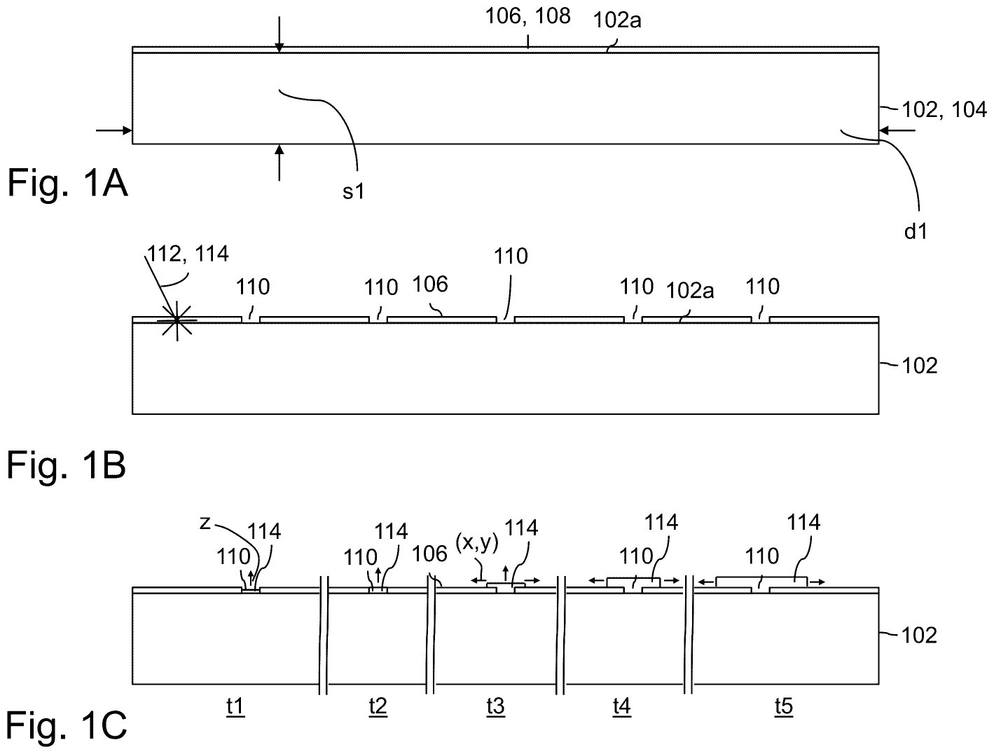

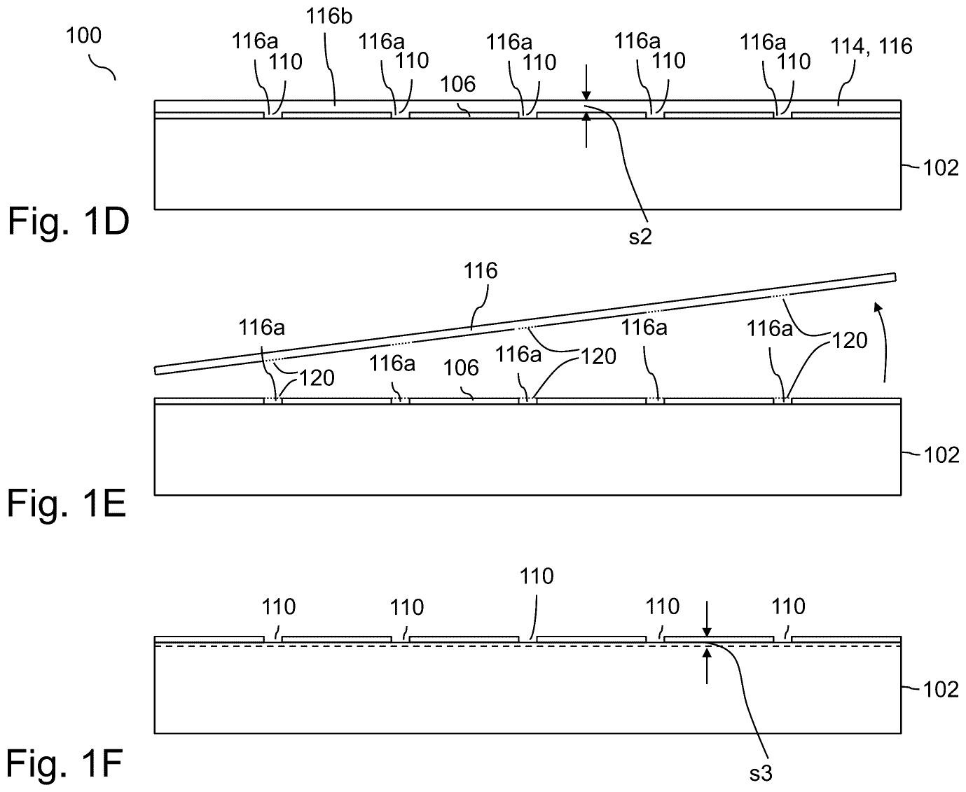

FIGS. 1A-1F show a method of manufacturing a semiconductor device, in accordance with an embodiment of the present disclosure. As shown, FIG. 1A shows a monocrystalline semiconductor substrate 102 (hereinafter referred to “the substrate 102”). The substrate 102 can be provided in the form of a wafer 104 of a given monocrystalline semiconductor material. Examples of such monocrystalline semiconductor material can include, but are not limited to, non-polar materials such as silicon (Si), germanium (Ge), tin (Sn), germanium tin (GeSn) and the like; polar materials such as III-N semiconductor materials (e.g., gallium nitride (GaN), aluminum nitride (AlN), indium gallium nitride (InGaN), aluminum gallium nitride (AlGaN)), III-V semiconductor materials (e.g., gallium arsenide (GaAs), indium phosphide (InP), gallium phosphide (GaP), indium gallium phosphide (InGaP), indium gallium arsenide (InGaAs)) and the like; oxide materials (e.g., gallium oxide (Ga₂O₃), zinc oxide (ZnO), strontium titanate (SrTiO₃), molybdenum dioxide (MoO₂), vanadium oxide (VO₂)); or any combination thereof. The substrate 102 can have a thickness s1 ranging between about 50 μm and 1000 μm, preferably between about 100 μm and about 775 μm, and most preferably between about 200 μm and 525 μm. The substrate 102 can have a circular shape, ovoid shape, rectangular shape or any other suitable shape. In some embodiments, the substrate 102 has an in-plane dimension d1 ranging between about 100 mm and 450 mm.

Still referring to FIG. 1A, graphene 106 covers the substrate 102. The graphene 106 can be provided in the form of a monocrystalline graphene layer 108 extending over and covering a planar face 102a of the substrate 102. In some embodiments, the monocrystalline graphene layer 108 is deposited onto the substrate 102 using an epitaxial deposition technique such as a chemical vapor deposition (CVD). In some other embodiments, the graphene 106 is provided in the form of a monolithic sheet of single layer graphene which is deposited onto the substrate 102.

As shown in FIG. 1B, the graphene 106 is altered to exhibit one or more openings 110 (hereinafter referred to as “the openings 110”) exposing the planar face 102a of the substrate 102 through the graphene 106. In some embodiments, the openings 110 are made by shining a high-energy beam 112 such as a plasma beam 114 (e.g., an oxygen-plasma beam, a nitrogen-plasma beam, an electron beam) at different locations of the graphene 106 covering the substrate 102. In such embodiments, the high-energy beam 112 is controlled so that some carbon atoms be ablated or otherwise removed from the graphene 106 while also maintaining a satisfactory integrity of the underlying portion of substrate 102. In some embodiments, an oxygen-plasma beam was exposed to specific regions of the graphene 106 during an exposition time ranging between about 10 s and 20 s, preferably between about 10 s and 15 s and most preferably between about 10 s and 12 s.

In some other embodiments, the openings 110 can be formed without necessarily using the high-energy beam 112. In such embodiments, the graphene deposition may be only partial. In other words, the graphene 106 is deposited only partially onto the substrate 102 in a way which leaves the openings 110. In some embodiments, one or more growth masks (hereinafter referred to as “the growth masks”) can be positioned onto respective portions of the substrate 102 prior to the graphene deposition. Then, the graphene deposition step can be performed in a way which would collectively cover the substrate and the growth masks altogether. The openings can then be revealed by removing the growth masks from the substrate. Although the openings 110 can be formed in a number of different manners, the use of the high-energy beam 112 to remove some of the carbon atoms and form the openings 110 can be most preferred as it tends to reduce the number of manufacturing steps and the required resources.

FIG. 1C shows a given monocrystalline semiconductor material 114 growing from the substrate 102 through the openings 110 at different moments in times t1, t2, t3, t4 and t5. These different moments in time are meant to be in chronological order, and are explained as such for understanding purposes only. However it is understood that in practice the growth of the given monocrystalline semiconductor material 114 occurs simultaneously in each of the openings 110. At moment in time t1, the given monocrystalline semiconductor material 114 is grown from an exposed substrate portion across the opening 110, and reach a midway point of the graphene 106 thickness along the transversal orientation z. At moment in time t2, the growth of the given monocrystalline semiconductor material 114 has reached a top point of the graphene 106. The growth of the given monocrystalline semiconductor material 114 does not stop once the openings 110 are fully filled with the given monocrystalline semiconductor material 114. In fact, such as shown at moment in time t3, the growth includes an overgrowth of the given monocrystalline semiconductor material 114 which extends laterally in all directions along the planar orientations x and y. The outgrowth of the given monocrystalline semiconductor material 114 is maintained through moments in time t4, t5 and beyond until the given monocrystalline semiconductor material 114 satisfactorily (e.g., fully) covers the graphene 106.

FIG. 1D shows the result of the overgrowth of the given monocrystalline semiconductor material 114 which leads to the formation of a monocrystalline semiconductor layer 116 on the graphene 106. The substrate 102, the graphene 106 and the monocrystalline semiconductor layer 116 collectively form a semiconductor device 100. As depicted, the monocrystalline semiconductor layer 116 has first base portions 116a anchoring to the substrate 102 via the openings 110, and a second sheet portion 116b connected to the first base portions 116a and covering the graphene 106. As depicted, the semiconductor device 100 has monocrystalline structures, also referred to as the first base portions 116a, extending between the substrate 102 and the monocrystalline semiconductor layer 116 across the openings 110. These monocrystalline structures supports the fact that the growth of the given monocrystalline semiconductor material 114 onto the substrate 102 is a crystalline epitaxial growth. The thickness of the monocrystalline semiconductor layer 116 is thicker when measured through the openings 110 and thinner when measured away from the openings 110. The thickness s2 of the monocrystalline semiconductor layer 116 can range from about 100 nm and 1 mm, preferably between about 150 nm and 10 μm and most preferably between about 200 nm and 1 μm.

FIG. 1E shows the monocrystalline semiconductor layer 116 being detached from the substrate 102. As depicted, with the detachments comes the breaking of the monocrystalline structures, e.g., the first base portions 116a, extending between the substrate 102 and the monocrystalline semiconductor layer 116. Such breaking can lead to surface roughness at the positions of the openings 110 of the substrate 102 and an under surface of the monocrystalline semiconductor layer 116. It is noted that such rough portions 120 can be polished using one or more polishing techniques including, but not limited to, mechanical polishing, chemical polishing and the like. It is understood that, once detached, the monocrystalline semiconductor layer 116 can be used as a semiconductor substrate for another semiconductor device or system. Moreover, it is encompassed that as the monocrystalline semiconductor layer 116 is generally thin, it can be flexible to a certain extent. Accordingly, the monocrystalline semiconductor layer 116 can be used for producing flexible semiconductor devices such as solar cells, and the like.

FIG. 1F shows an example re-use of the substrate 102. As depicted, the remains of the broken monocrystalline structures are cleaned or otherwise removed from the openings 110, thereby leaving a substrate 102 having graphene 106 with openings 110, ready for another growth step. In some other embodiments, a given thickness s3 of the remainder of the substrate 102 is polished or otherwise removed, up to the dashed line, which frees the substrate 102 from the graphene 106. In these embodiments, a new graphene layer can be deposited, new openings can be formed and so forth, until a new monocrystalline semiconductor layer is formed onto the re-used substrate.

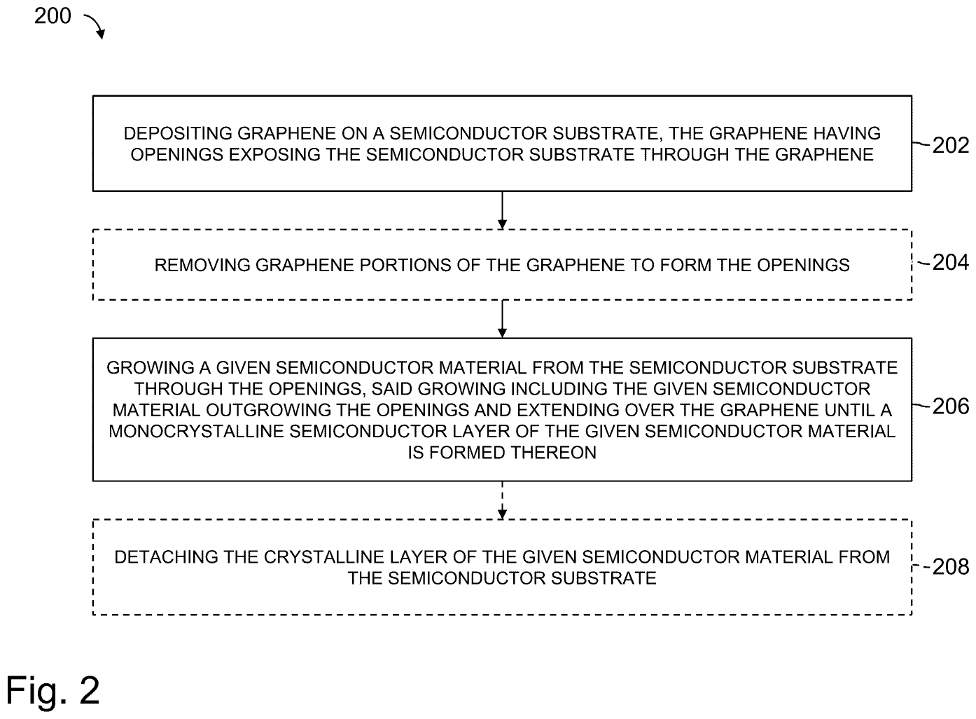

FIG. 2 shows a flow chart of an example of a method 200 of manufacturing a semiconductor device, in accordance with an embodiment of the present disclosure.

At step 202, graphene is deposited on a substrate. As discussed above, the substrate can be made of a non-polar monocrystalline semiconductor material such as monocrystalline germanium and monocrystalline silicon. Otherwise, the substrate can be made of a polar monocrystalline semiconductor material.

At step 204, one or more graphene portions of the graphene are removed, thereby forming corresponding one or more openings exposing the substrate through the graphene. The step 204 can involve a step of projecting a plasma beam (or any other suitable high-energy beam) towards the graphene portions for the removal. When the plasma beam carries an intensity value exceeding an opening forming intensity threshold, the carbon atoms are ejected or otherwise removed from the layer thereby forming the opening. In some embodiments, the plasma beam can be an oxygen-plasma beam or a nitrogen-plasma beam. Other plasma beam can be used in some other embodiments. The step 204 of removing the graphene portions can be omitted in embodiments where the graphene is only partially grown onto the substrate. As such, the graphene deposition can be limited to only a given portion of the substrate, the remaining portion(s) of the substrate corresponding to the opening(s). The graphene portions that are removed (or where graphene hasn't been deposited) are preferably sufficiently spaced apart from one another. In some embodiments, the openings are formed into a regular, equidistant pattern. However, in some other embodiments, the openings are formed into an irregular and arbitrary pattern. The number of openings can vary from an embodiment to another. For instance, the openings can collectively cover at least 5% of the area of the overall graphene layer, preferably at least 10% of the area of the overall graphene layer and most preferably at least 15% of the area of the overall graphene layer.

At step 206, a given monocrystalline semiconductor material is grown from the substrate through the openings. The step 206 further includes a step of outgrowing the given monocrystalline semiconductor material from the openings and extending over the graphene until a monocrystalline semiconductor layer is formed on the graphene. In some embodiments, the step 206 includes the formation of monocrystalline structures extending between the monocrystalline semiconductor substrate and the monocrystalline semiconductor layer across the openings. It is hypothesized that the crystallinity of such structures extending through the openings allows the monocrystalline growth of the given monocrystalline semiconductor material atop the graphene. If the openings were to be too small, such monocrystalline structures would not be formed within the openings, and then only undesirable polycrystalline growth would be obtained above the graphene. As such, the openings typically include a few atoms, to many atoms, missing from the graphene lattice. Accordingly, the openings may have an in-plane dimension corresponding to a few missing carbon atoms, or more than a few missing carbon atoms. In some embodiments, the openings have an in-plane dimension of at least 0.5 nm, preferably at least 1 nm and most preferably at least 5 nm. In some embodiments, the opening can for example have a maximal in-plane dimension of at most 150 nm, preferably at most 100 nm and most preferably at most 50 nm. In some embodiments, the substrate can be made of the given monocrystalline semiconductor material. In these embodiments, the same monocrystalline semiconductor material forms the substrate, the monocrystalline structures extending within the openings and the monocrystalline semiconductor layer. However, in some other embodiments, it is encompassed that the substrate can be made of a first monocrystalline semiconductor material different from the given monocrystalline semiconductor material of the monocrystalline semiconductor layer. In these embodiments, the first monocrystalline semiconductor material has a first crystalline lattice parameter matching, or slightly matching, a second crystalline lattice parameter of the given monocrystalline semiconductor material. It was found that some semiconductor material combinations may not be preferred as crystalline lattice parameters may be too different to allow monocrystalline growth within the openings. As such, in some embodiments, the semiconductor device can be a Ge/Gr/Ge, III-V/Gr/Ill-V, or a III-N/Gr/Ill-N heterostructure. In some other embodiments, the semiconductor device can be a III-V/Gr/Ge, Ge/Gr/Si, III-N/Gr/Ge or a III-V/Ge/Gr/Ge heterostructure. Other materials such as silicon or suitable oxides can be used as well in any of the above-mentioned heterostructures. For instance, a III-N/Gr/Si heterostructure can be envisaged as well.

At step 208, the monocrystalline semiconductor layer is detached from the substrate. In some embodiments, an outer portion of the monocrystalline semiconductor layer can be pulled away from the substrate until the whole monocrystalline semiconductor layer follows. In some other embodiments, a suction-like force can be exerted onto the monocrystalline semiconductor layer to pull it away from the substrate. The detachment can be performed in any other suitable way. It is understood that the step 208 of detaching can be omitted in some circumstances. For instance, the semiconductor device incorporating both the substrate and the monocrystalline semiconductor layer can be sold as a semiconductor device in some embodiments. It is understood that the thickness and width of the openings can have an impact on the force required for the step 208 of detaching. Accordingly, in some embodiments, fewer and thinner openings are preferred to facilitate the detachment of the monocrystalline semiconductor layer. However, in some other embodiments, a greater number of larger openings may be used as well.

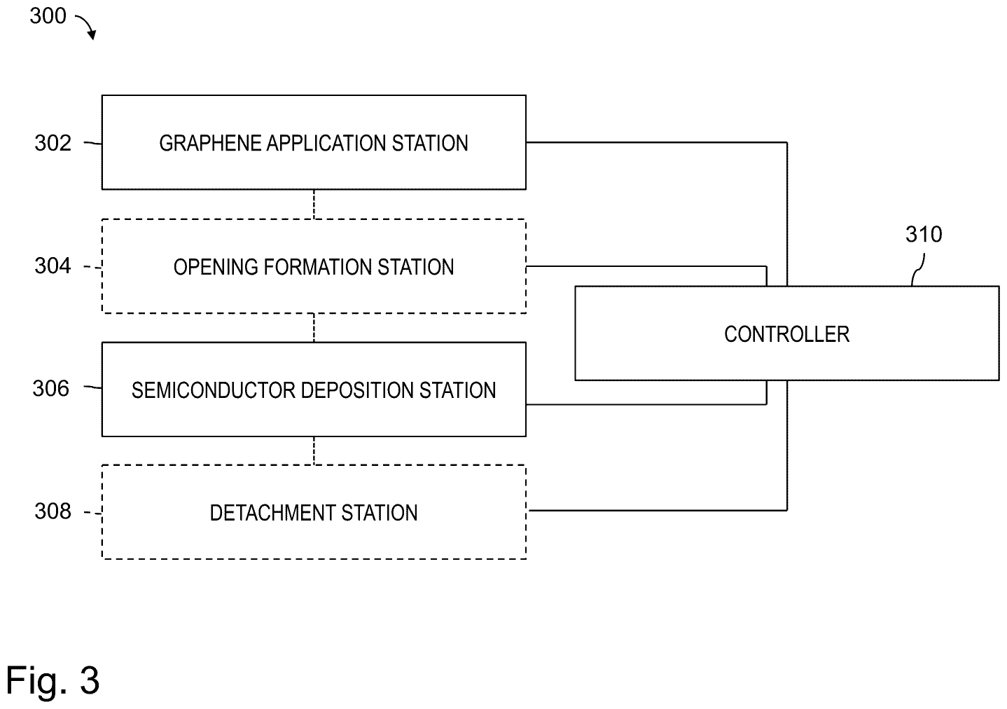

The processing steps described above with reference to FIG. 2, as well as other processing steps described below, can be performed using a substrate manufacturing system 300, an example of which is shown in FIG. 3. As depicted, the substrate manufacturing system 300 has a graphene application station 302, an opening formation station 304, a semiconductor deposition station 306, and a detachment station 308 in this embodiment. Other potential stations may be part of the substrate manufacturing system 300 in some embodiments.

For instance, the graphene application station 302 can perform the graphene deposition steps discussed above with reference to FIGS. 1B and 2. More specifically, the graphene application station 302 is configured for receiving the graphene-free substrate and for depositing graphene, or graphene portions, on an exposed face of the substrate. The deposition may involve any suitable graphene deposition or application process including, but not limited to, CVD, photolithography and the like. The graphene application station 302 is able to control the thickness of the graphene deposition as desired.

As shown, the opening formation station 304 is downstream from the graphene application station 302 along the manufacture process. The opening formation station 304 is optional, as discussed above. However, in the embodiments where such a station is used, it is configured to receive the graphene-deposited substrate from the graphene application station 302. The opening formation station 304 can include an enclosure, and a high-energy beam generator operated within the enclosure. The graphene portion removal preferably occurs within the enclosure which prevents the high-energy beam to shine outside for safety purposes.

The semiconductor deposition station 306 is downstream from the graphene application station 302 and the opening formation 304 along the manufacture process. The semiconductor deposition station 306 is configured for depositing the given monocrystalline semiconductor material atop the graphene of the substrate. Both the steps of growing the base portions extending within the openings and the step of outgrowing the given monocrystalline semiconductor material to form the graphene sheet connected to the base portions are performed using the semiconductor deposition station 306. Preferably, the growing and the outgrowing steps are performed in one continuous step, although these growing steps can be performed in many separate steps in some other embodiments.

The detachment station 308 is downstream from the semiconductor deposition station 306 along the manufacture process. As can be expected, the detachment station 308 is configured for breaking the monocrystalline structures extending between the substrate and the monocrystalline semiconductor layer within the openings, and for pulling the monocrystalline semiconductor layer away from the substrate. The construction of the detachment station 308 depends on the detachment technique that is preferred, which will appear to the skilled person.

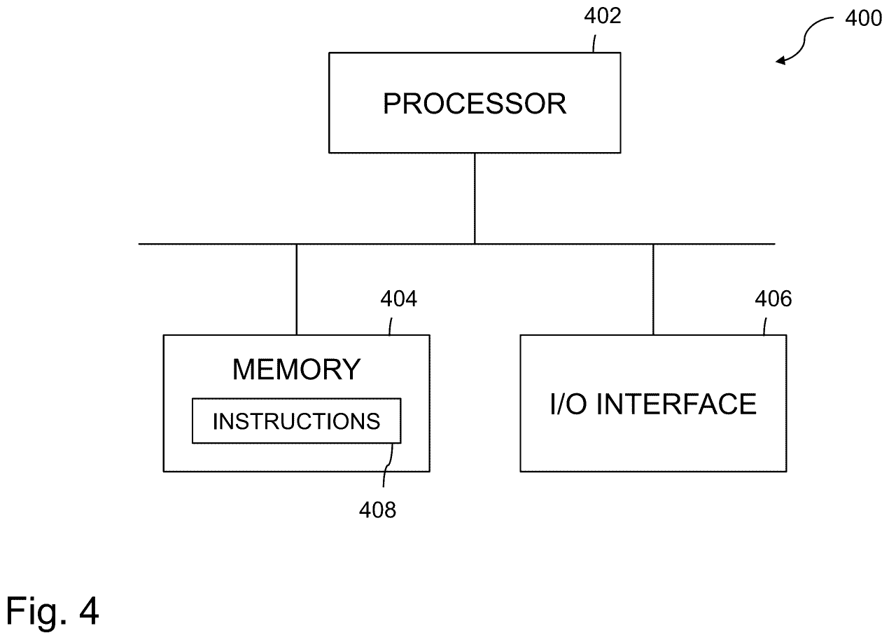

As shown in the depicted embodiment, the stations 302, 304, 306 and 308 can be communicatively coupled to a controller 310 controlling each of the stations and components thereof sequentially performing processing steps on the substrate discussed above. The controller 310 can be provided as a combination of hardware and software components. In some embodiments, the controller 310 encompasses any controller portions which may be part of some of the individual stations. As such, regardless of the controller portions being separate from one another, and because the controller portions are communicatively coupled to one another, they form the controller 310. The hardware components can be implemented in the form of a computing device 400, an example of which is described with reference to FIG. 4.

Referring to FIG. 4, the computing device 400 can have a processor 402, a memory 404, and I/O interface 406. Instructions 408 for performing at least some of the processing steps discussed herein can be stored on the memory 404 and accessible by the processor 402.

The processor 402 can be, for example, a general-purpose microprocessor or microcontroller, a digital signal processing (DSP) processor, an integrated circuit, a field-programmable gate array (FPGA), a reconfigurable processor, a programmable read-only memory (PROM), or any combination thereof.

The memory 404 can include a suitable combination of any type of computer-readable memory that is located either internally or externally such as, for example, random-access memory (RAM), read-only memory (ROM), compact disc read-only memory (CDROM), electro-optical memory, magneto-optical memory, erasable programmable read-only memory (EPROM), and electrically erasable programmable read-only memory (EEPROM), Ferroelectric RAM (FRAM) or the like.

Each I/O interface 406 enables the computing device 400 to interconnect with one or more input devices, such as keyboard(s), mouse(s) and the like, or with one or more output devices such as display(s), memory system(s), network(s) and the like. The I/O interface 406 can also enable the computing device 400 to interconnect with the stations 302, 304, 306 and 308, or to components thereof including, but not limited to, crystalline semiconductor material source(s), graphene source(s), robotized arm(s) and the like.

Each I/O interface 406 enables the controller 310 to communicate with other components, to exchange data with other components, to access and connect to network resources, to server applications, and perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fiber optics, satellite, mobile, wireless (e.g. Wi-Fi, WIMAX), SS7 signaling network, fixed line, local area network, wide area network, and others, including any combination of these.

The computing device 400 and any software application operated by the computing device 400 described herein are meant to be examples only. Other suitable embodiments of the controller 310 can also be provided, as it will be apparent to the skilled reader.

### Example—Unravelling the Influence of Plasma Induced-Defects During the Hetero-Integration of 3D Semiconductors on Graphene by Anchor Point Nucleation

The monolithic hetero-integration of three-dimensional (3D) bulk materials and 2D layered materials has sparked great interest since their extraordinary intrinsic properties can be conjugated to obtain unique functionalities arising from the physical stacking of such materials. Van der Waals epitaxy (VdWE) can theoretically enable epitaxial growth of crystalline 3D semiconductors on 2D materials, while circumventing the lattice and thermal mismatch issues, thereby extensively reducing defect density in the epilayers. However, while the VdWE of 2D/3D heterostructures has been well established, the epitaxial growth of single-crystalline 3D on 2D heterostructures is an ongoing challenge. This is mainly due to the dissimilar lattice structure and chemical bonding across the interfaces between 3D and 2D materials, but also the low surface energy of 2D materials.

Remote epitaxy has been proposed as a promising technique to circumvent these limitations and achieve high-quality single-crystalline layers. In this approach, graphene is used as an interlayer and the epitaxial memory is achieved via remote interactions that permeate through graphene. This technique has been applied for the growth of single-crystalline III-V, III-N semiconductors compounds, and other materials including metals, complex oxides, Halide perovskites, etc. However, since this technique is governed by the polarity of the underlying substrate, thereby it is only suitable for polar materials, excluding all the applications based on non-polar materials including Silicon (Si) and germanium (Ge). Also, despite outstanding achievements and a great progress in understanding the underlying physics and principles of remote epitaxy, it is currently subject to a huge contradictory debate in the scientific community about the underlying mechanisms governing this technique. It is even reported that any deviation from a perfect, defect-free and pristine graphene interface will influence the formation of remote epitaxial single-crystalline layers. This is a huge challenge due to the fact that ensuring a perfect interface is quite impossible since graphene cannot be grown directly on arbitrary substrates and therefore it required additional transfer steps that can introduce defects including point defects, wrinkles, residues and mechanical damage. All these challenges make remote epitaxy limited and very difficult to reproduce in a controllable manner. Therefore, there is proposed an alternative technique that can alleviate those limitations for obtaining perfectly single-crystalline layers in a reliable manner.

In this example, we propose an original and universal approach called anchor point nucleation (APN) based on graphene engineering by plasma treatment to monolithically grow defect-free single-crystalline semiconductors on graphene-terminated substrates (including non-polar). The anchor points can broadly be referred to as openings. As discussed above, the anchor points or openings in the graphene can be formed using non-plasma-based methods as well. This example demonstrates that using plasma treatment, openings can be introduced in the graphene layer that improves its surface reactivity and adhesion with other materials. Those openings (which can also be referred to as “defects”) act as preferential nucleation sites for the epitaxial growth. Defect engineering using other methods has been previously reported for the epitaxial growth of 2D heterostructures. However, this example is the first time that such an approach is used for the growth of semiconductor compounds on non-polar materials such as germanium and silicon. Moreover, the nature of the induced openings, their role in the epitaxial growth and the underlying mechanisms for such a technique are elucidated for the very first time to the best of our knowledge. Here, it was found that the induced openings are mainly openings depending on the treatment durations. The experimental data provide a clear corroboration for the role played by the induced defect during the nucleation process. It was found that the APN approach is governed by the nucleation in the openings followed by an overgrowth of a continuous layer thereover. The combination of HRTEM measurements and strain mapping demonstrates that the APN method enables the epitaxial growth of defect-free single-crystalline Ge layers without any deformation on a graphene-terminated Ge substrate. The results presented in this example demonstrate that the APN approach is a powerful technique that is suitable for the epitaxial growth of 3D semiconductors on graphene and is a promising solution to circumvent the limitations of remote epitaxy.

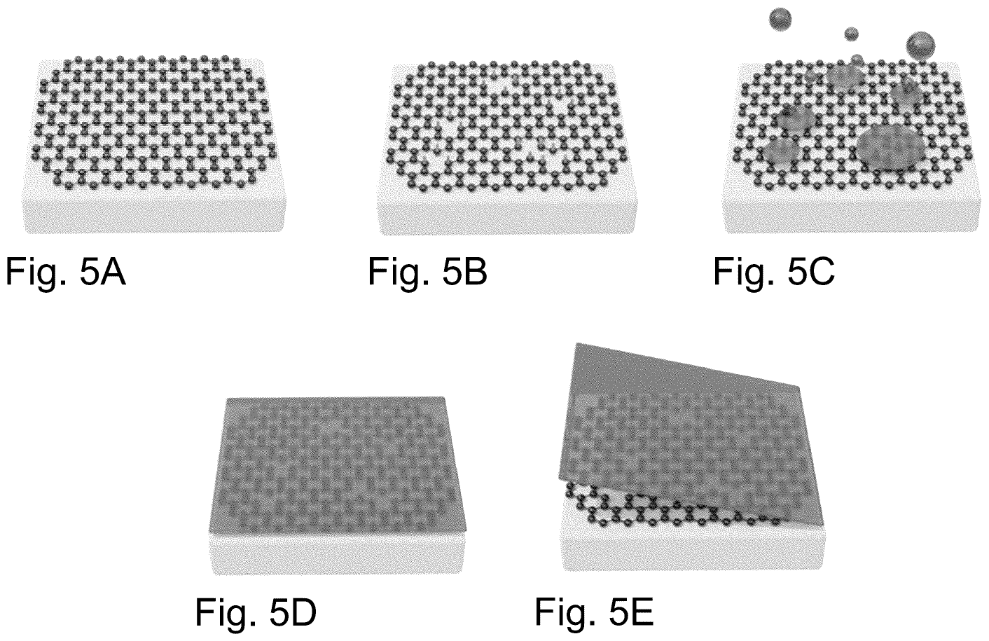

FIGS. 5A-E show the schematic representation of the Anchor Point Nucleation (APN) processing steps that enhance the reactivity of graphene and enable the growth of monocrystalline layers on single layer graphene (SLG). This approach is based on the controlled introduction of openings in the SLG, which will act as preferential nucleation sites allowing to anchor adatoms on the graphene surface. To achieve this, first, large-area SLG is transferred on the substrate using wet transfer technique, as shown in FIG. 5A. As best shown in FIG. 5B, the substrate is then treated by plasma to introduce openings in the SLG. These openings significantly enhance the surface energy of the graphene and serve as preferential nucleation sites for the epitaxial growth. Moreover, the openings provide a direct link between the substrate and epilayer enabling substrate-oriented growth even for elemental materials. It is worth mentioning that the use of plasma treatment can be more advantageous compared to other patterning techniques such as photolithography and electrolithography, which are complex, expensive and use photoresist. In contrast, the plasma-based technique is easy to use, cost-effective, simple without multistep processes and it enhances the cleaning of PMMA residues from wet transferred graphene, preventing random nucleation that will result in 3D growth. After the formation of the openings via plasma treatment, the nucleation of semiconductor islands grow preferentially from the openings and onto the engineered graphene layer, as per FIG. 5C. The nucleation within openings allows the islands to be oriented by the underlying substrate. Referring now to FIG. 5D, the opening mediated nucleation is then used as a seed layer to grow complete epitaxial layer through the overgrowth of the islands. FIG. 5E shows that the epitaxial layer of monocrystalline semiconductor material grown onto the graphene can be peeled or otherwise detached from the remainder of the semiconductor substrate. The epitaxial layer can then be used as a substrate for another semiconductor device.

A key challenge of the APN approach is to prevent a complete etching of the atomically thin SLG and introduce the openings in a controlled manner. To this end, a balance between the duration and the power of the plasma has been established to slightly damage the SLG, while maintaining its nature and coverage on the substrate. This was not an easy task since the graphene can be easily etched away by standard plasma etching techniques. Indeed, this example indicates that a very light plasma treatment in short burst should preferably be used to avoid complete removal of the SLG on the surface. To further elaborate on these findings, the effects of O2 plasma etching on the SLG quality were thoroughly investigated by Raman spectroscopy and X-ray photoelectron spectroscopy (XPS) measurements, such as discussed below.

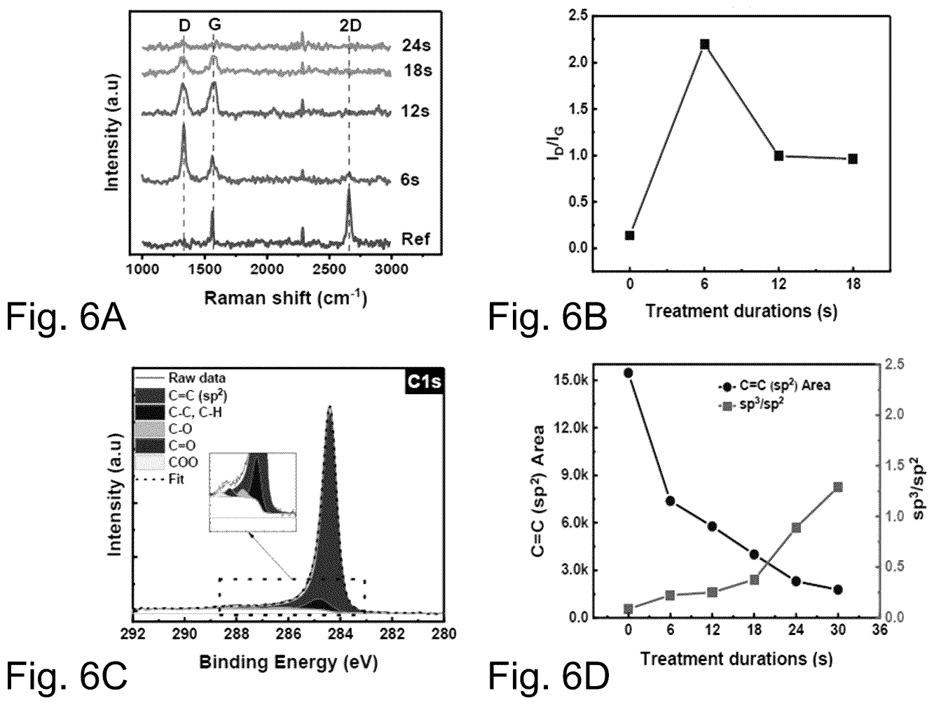

FIG. 6A shows Raman spectra of transferred SLG on Ge substrate for different durations of plasma treatment. The Raman spectra consist of a set of distinct peaks. The G band is related to C—C bond stretching in sp2 carbon systems, the D band is related to defects (such as openings) and disorder, and the 2D band is the second order of the band D, but does not require a defect or an opening. The non-treated SLG shows very sharp G and 2D bands with a very low D band, demonstrating the high-quality graphene layer with large crystallite sizes. The ratio of the D to G intensities (ID/IG) is inversely proportional to the crystallite size. The apparition of D band and significant reduction of 2D band after the application of plasma treatment show a clear evidence of opening introduction inside the graphene layer. The ID/IG ratio as a function of treatment duration extracted from FIG. 6A is shown in FIG. 6B. A sharp initial increase of the D band is observed up to 6 s and then it decreases with the increase of the duration. During the initial stages of the treatment, it is believed that mainly dangling bonds and atomic vacancies are introduced in the SLG. As the duration increases larger openings are formed in the SLG causing a significant reduction in the graphene crystallite size. From FIGS. 6A and 6B, it is concluded that up to 18 s of treatment, the SLG is being transformed from pristine graphene to nanocrystalline graphene with smaller crystallite size. Such transformation is characterized by the appearance of D band and the increase of ID/IG and the broadening of all the peaks. Above 18 s of plasma treatment, the nanocrystalline graphene is transformed to low sp3 amorphous carbon. In such durations, it is observed that the total disappearance of the D and G bands means that the graphene layer is completely etched away.

To further investigate the defect introduced in SLG, XPS measurements were performed to measure spectra of C1s core level and to study the nature of chemical bonds in engineered graphene. FIG. 6C shows the high-resolution C1s spectrum of a non-treated SLG. This spectrum contains mainly the sp² carbon peak centred at 284.4 eV. The analysis of the XPS spectra after the plasma treatment is presented in FIG. 6D showing the C═C sp2 bond area (blue) and the sp3/sp2 bond ratio (red) for different treatment durations. After, the plasma treatment, the full width at half maximum (FWHM) of the C1s peak became broader. From FIG. 6D, it can be seen that the C═C sp2 area decreases with the increase of treatment duration, while the ratio sp3/sp2 increases as more and more openings are generated in the SLG. This clearly demonstrates the introduction of openings in the graphene. Initially, the sp2 area decreases rapidly due to the generation of dangling bonds. As the openings start to grow by merging multiple atomic vacancies, the slope of the curve of sp2 area decreases. These observations are in good agreement with the Raman spectroscopy measurement presented in FIGS. 6A and 6B.

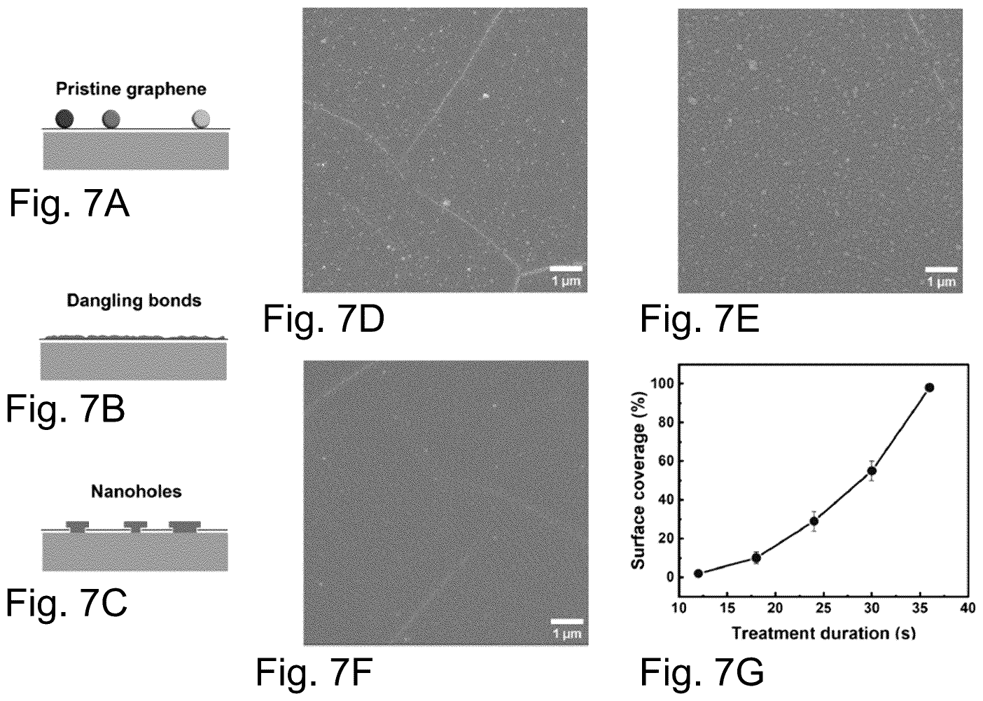

To bring new insight on the influence of openings in SLG on epitaxial growth, the impact of plasma treatment on epitaxial nucleation of few nm of Ge was studied on the treated SLG. On pristine graphene, the formation of seeds is difficult due to the SLG very low surface energy, which makes epitaxial nucleation very challenging because the adatoms barely stick to the surface and the nuclei can be easily desorbed before reaching the critical size. Such nucleation results in a 3D growth mode as schematically illustrated by FIG. 7A. As stated above, very short duration of plasma treatment introduces mainly dangling bonds and atomic vacancies, which help to increase the wettability of graphene and therefore significantly enhance its reactivity. Even though those dangling bonds enhance the nucleation on the SLG by acting as preferential nucleation sites as represented in FIG. 7B, the resulting layer cannot be epitaxially oriented by the substrate underneath the graphene layer since there is no direct link between them. For treatment of 12 s and above, the growth of seeds with crystal form is observed, which is clear evidence of the opening formation in the SLG. In contrast to dangling bonds, such openings provide a direct link with the substrate underneath the SLG that enables direct epitaxial growth of substrate-oriented seeds, as shown in FIG. 7C. The opening-mediated nucleation must be dominant to grow epitaxially monocrystalline layers on top of engineered graphene. For all the treatments presented in this figure, the growth temperature was 400° C. and the thickness is 5 nm. For short durations (up to 6 s), the APN is proceeded through dangling bonds and for longer durations through the openings induced in the graphene layer.

By increasing time of plasma treatment, more openings are introduced in the SLG structure and their size increases. FIGS. 7D-F show SEM micrographs tracking the evolution of the nucleation of Ge on treated SLG at durations of 18 s, 24 s and 30 s, respectively. From these images, it can be seen that the density and the size of the seeds are increasing with treatment duration. The increase in the crystal size is due to larger openings. For further understanding, the surface coverage by the seeds is plotted as a function of treatment duration, the results of which are shown in FIG. 7G. It was found that the surface coverage is proportional to the treatment duration. This could be explained by the fact that as the duration increases larger regions not covered by the graphene enabling the nucleation of larger seeds directly on the substrate. When the SLG is totally etched away (above 30 s of treatment), the seeds form a continuous and homogeneous layer.

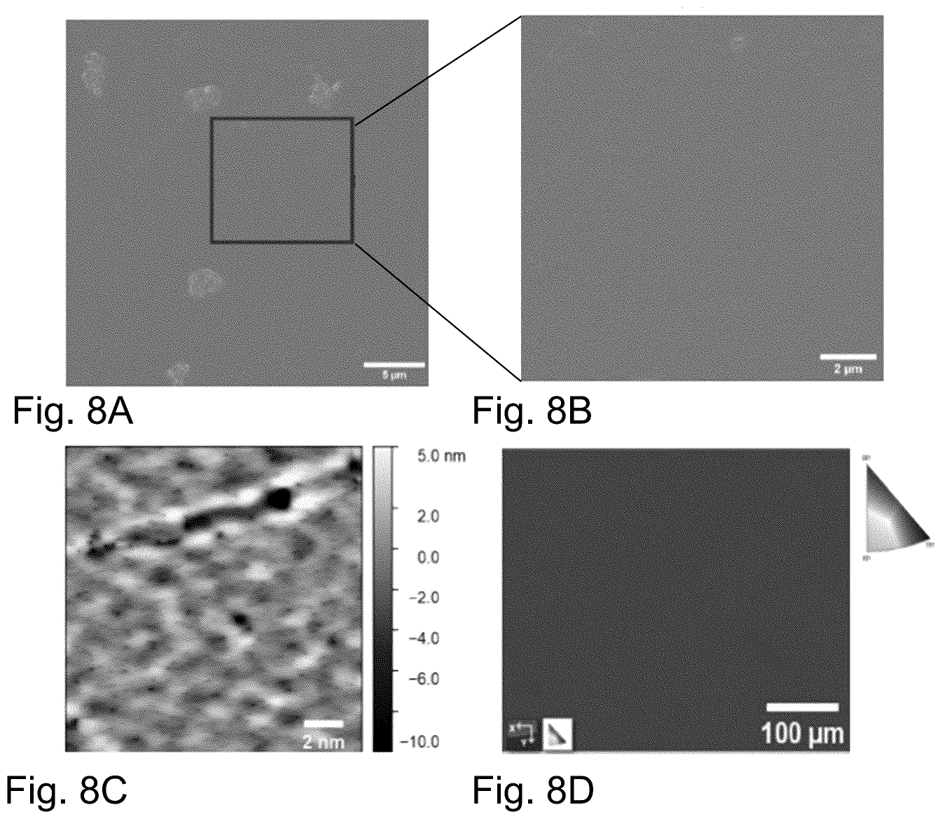

After unravelling the different mechanisms of nucleation involved in the APN approach, the epitaxial growth of Ge layers on the engineered SLG supported by a Ge (100) substrate is performed. FIGS. 8A and 8B show plan view scanning electron micrographs (SEM) of the as-grown epilayer. The SEM images show homogeneous and smooth surfaces of the 500 nm-thick Ge layers attesting their high morphological quality. In FIG. 8A, few defects can be observed, which were attributed to the poly-nucleation induced by the multilayer graphene. This can also be seen in the FIGS. 6A-D showing the SEM images of the early stages of the nucleation. However, without the multilayer of graphene, the epilayer surface is quite homogenous, as shown in FIG. 8B. The morphological quality of the epilayers was also investigated by AFM and the resulted image is displayed in FIG. 8C. From this figure, a featureless and smooth surface with an RMS roughness of 2 nm can be appreciated. The electron backscattering diffraction (EBSD) map of the top surface presented in FIG. 8D reveals that the Ge epilayers grown on the engineered SLG are perfectly single-crystalline and have the same crystal orientation than the Ge (100) substrate. This demonstrates that the epilayer is oriented by the underneath substrate through the induced openings. On pristine SLG, the as grown layers are polycrystalline. In contrast, the new APN approach suggested herein based on the engineering of graphene successfully demonstrated the growth of continuous and smooth layer on a non-polar substrate for the very first time. So far, this is impossible to achieve with the so-called remote epitaxy since it is governed by the polarity of the substrate beneath graphene.

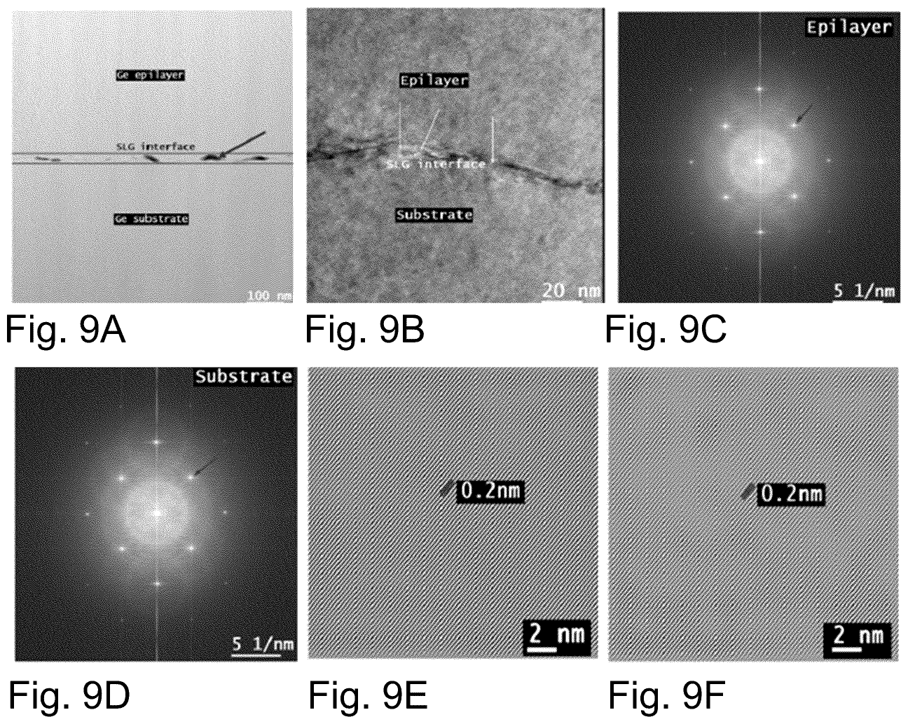

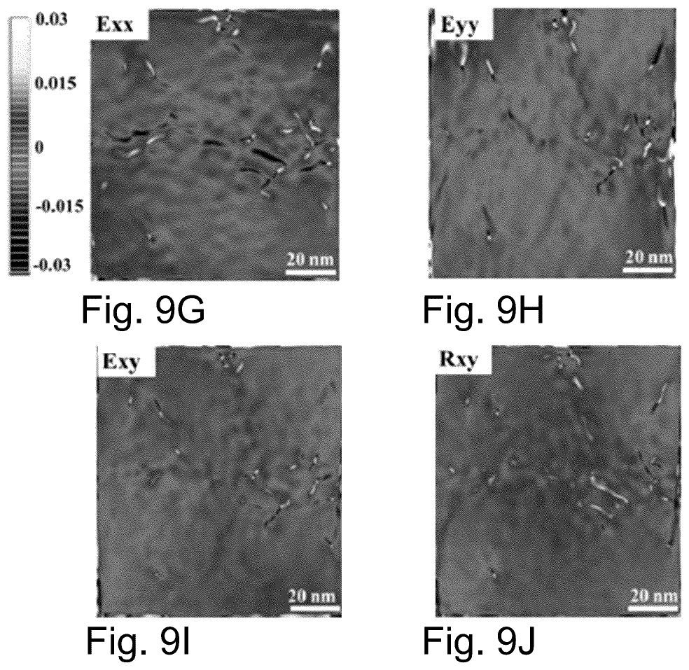

To further investigate the crystalline quality of the as-grown layers by the APN approach, cross-sectional transmission electron microscopy (TEM) measurements were performed. FIGS. 9A-J show the TEM analysis of Ge epilayers grown on engineered SLG. The cross-sectional high-angle annular dark-field STEM (HAADF-STEM) of the epitaxial structure is presented in FIG. 9A. From this figure, it can be seen that the epilayer is made of a continuous Ge epilayer, so as the engineered SLG interface and the Ge substrate. Some small holes were noticed and pointed at with arrows, which were attributed to the overgrowth of Ge on the SLG once the nucleation is initiated in the openings. This observation is in good agreement with the proposed mechanism for the APN approach as discussed above. FIG. 9B shows the cross-sectional high-resolution TEM image of the epitaxial structure where the SLG interface (dark contrast) can be observed clearly between the epilayer and the substrate. Through the dark interface representing the perfect graphene layer, some small discontinuities (highlighted by arrows) indicating the induced openings can be noticed. This observation confirms that the SLG still exists after the Ge growth, indicating that the graphene is not damaged under the used growth conditions and still maintains its nature. From this HRTEM image, there is clear evidence of absence of structural defects in the epilayer, which demonstrates the high structural quality of the as-grown layers by APN. FIGS. 9C and 9D display the fast Fourier transform (FFT) patterns of the epilayer and the underlying substrate shown in FIG. 9B, respectively. It can be noticed that these patterns are perfectly similar, indicating the same structure. This result confirms the epitaxial relationship between the epilayer and the substrate and clearly demonstrates the single-crystalline nature of the as-grown layers. As mentioned previously, the epilayer is oriented by the underlying substrate because the nucleation through the openings is dominant. The Ge epilayers and the substrate structure is diamond cubic as shown in FIGS. 9E and 9F displaying the inverted fast Fourier transform (IFFT) images that show the (220) planes of the epilayer and the substrate, respectively, with a d-spacing of ˜ 0.2 nm.

To clarify the mechanisms of how the epilayers relieve the deformations and the epitaxial stress, the strain state of the as grown Ge layers on engineered SLG was studied by HRTEM (FIG. 9B) combined with the geometrical phase analysis (GPA) method. The 2D strain and rotation maps of Ge/SLG/Ge are presented in FIGS. 9G-J. The analysis of those maps provides clear evidence that there is no deformation and strains in the Ge epilayers in respect to the underlying substrate. This confirms that the growth is coherent without strain relaxation and comparable to homoepitaxy. From the in-plane map (Exx), it can be noticed that a very low negative out-of-plane deformation in the SLG interface that could be attributed to the nucleation on the graphene dangling bonds. However, in the regions that were considered as openings (FIG. 9B), the in-plane deformation is zero (Exx=0). These observations perfectly corroborate the mechanisms governing the APN approach that we presented in the previous sections. The quality of such layers is suitable for high-performance hybrid devices.

In this example, an approach called anchor point nucleation is proposed. This approach is a universal method to monolithically integrate 3D semiconductors on 2D materials. For the first time, the epitaxial growth of defect-free single-crystalline Ge layers without any deformation on engineered SLG was realized. The engineering of graphene by oxygen-plasma introduces defects namely openings, which act as preferential nucleation sites that enable the nucleation and growth of high-quality epilayers. HRTEM and STEM results provide a clear evidence that the layers are perfectly single-crystalline without any deformation and strain. Those defect-free layers are not only single-crystalline, but also perfectly aligned and oriented by the substrate underneath the graphene layer. This example thus demonstrates that the growth is governed by the nucleation through openings followed by an overgrowth of the nuclei anchored on the substrate and a coalescence of a continuous layer.

Compared to remote epitaxy, the APN approach is a technique that can produce high-quality single-crystalline layers of semiconductors on any substrate including nonpolar substrate, whereas the remote epitaxy that is governed by the polarity of the substrate can only work for polar substrates. The above-discussed findings provide new insights on plasma-induced defects in SLG and open up a new route for the growth of hybrid functional devices. Few recent works reported on a similar technique called lateral seeded epitaxy, where the nucleation is induced by defects. This example demonstrates that defect-induced anchor points are promising for the epitaxial growth of any 3D semiconductors (polar and nonpolar) on a graphene-terminated non-polar substrate and alleviates the limitations of remote epitaxy.

Regarding graphene transfer, commercially available PMMA/SLG on polymer support is slowly immersed in deionized water (DIW) until the PMMA/SLG layer is released from its support and is floating on top of the DIW. Before the transfer, the Ge (001) substrate was previously deoxidized in HBr for 1 min and rinsed with DIW. In fact, it was demonstrated that HBr can effectively remove suboxides on Ge surfaces. This deoxidized substrate is introduced into the DIW and is used to carefully scoop out the PMMA/SLG from below. The Ge substrate with PMMA/SLG is then dried for 30 min in ambient clean room air, followed by annealing on hot plates at 150° C. for 1 h. The sample is then stored for 24 h under the vacuum to avoid any detachment of the SLG and to remove all the residual moisture. Finally, to clean the SLG, the PMMA is dissolved in acetone and isopropyl alcohol (IPA) at 50° C. for 15 min in each. This part is crucial to obtains PMMA-free SLG surface, because any remaining polymer residue will result in unwanted nucleation leading to polycrystalline growth.

Concerning plasma treatment, the SLG/Ge substrate is treated by oxygen (O2) plasma process to introduce defects in the SLG. The O2 plasma treatment is performed in a barrel type chamber, under a pressure of 320 mTorr and a radio frequency (RF) power of 10 W. The treatment duration varies between 6 and 60 s. It is worth to mention that increasing the RF power significantly accelerate the etching process, leading to complete destruction of the SLG. This aspect was carefully optimized during the experiments.

Epitaxial Growth was carried out in VG Semicon VG90F CBE reactor, with liquid nitrogen cryopanel and with a thermocouple as a means of monitoring the temperature during the growth. Prior to epitaxial growth, all samples were annealed at 600° C. during 10 min to thermally deoxidized the revealed parts of Ge substrate and to help eliminate any potential residues of PMMA from the transfer. The Ge was grown at 520° C. at chamber pressure of ˜6E-6 Torr, using a solid source of Ge with a K-Cell temperature at 1250° C.

Raman spectroscopy is performed using Horiba Raman spectrometer with a CCD detector and a laser with an excitation wavelength of 474 nm to analyze defects induced in SLG by plasma treatment. A 100× objective was used for the measurements, which results in a laser spot of ˜1 μm in size. Before the data analysis, the background noise was subtracted. The D:G band ration was calculated directly from the maximum intensity of the bands.

X-ray photoemission spectroscopy is realized with Kratos Axis Ultra spectrometer using a monochromatic Al Kα source (hv=1486.7 eV) and a charge neutralized system. Survey scans and high-resolution scans are performed with an analysis area of 300×700 μm. The samples were loaded in the chamber, right after the plasma treatment, to avoid contaminations from ambient exposure. The XPS spectra is corrected to the main line of carbon 1s spectrum set to 284.8 eV. The data are analyzed using CasaXPS software. The Shirley background is subtracted from the XPS spectra, which is then fitted using a Voigt function.

The surface morphology of the nucleation and epitaxial layers is observed with a scanning electron microscope Zeiss LEO 1540 XB at 4.3 mm of working distance and 5 keV of acceleration voltage and with an atomic force microscope Veeco Dimension 3100 in tapping mode using SSS-NCHR silicon probe.

Prior to Scanning Transmission Electron Microscopy (STEM) and TEM imaging, the samples were prepared by focused ion beam (FIB) thinning and ion milling using a Zeiss NVision 40 Focused Ion Beam. The surface was protected by carbon coating to avoid the sputtering of the surface by ion beam. The TEM and STEM observations were made in Titan Themis microscope operated at 200 kV and equipped with a CEOS probe corrector and Ceta 16M camera from FEI. The data were treated using Gatan digital micrograph software, to evaluate the crystalline quality and strains of the layers.

As can be understood, the examples described above and illustrated are intended to be exemplary only. The semiconductor device described herein can be used in many applications including, but not limited to, electronics, optoelectronics (e.g., light-emitting diodes, photodetectors), information technology, healthcare (e.g., medical devices), telecommunications (e.g., mobile telecommunications), energy (e.g., solar energy), defence, to name few examples. The semiconductor device can be made flexible, portable and/or optically transparent, depending on the embodiment. For instance, although the openings that were shown in the figures are closed openings, it is encompassed that the openings can be open-ended in some embodiments. For instance, openings made close to an edge of the graphene layer can be open to the adjacent void. In some embodiments, the layer is transferred to another substrate which can dissipate heat well. For instance, in the case of gallium nitride (GaN) based LEDs, these devices have to be transferred to a heat dissipating substrate as their natural hosts does not dissipate heat well. As can be understood, the process disclosed herein can be applied to large surfaces in an advantageous, industrial manner. The scope is indicated by the appended claims.

What is claimed is:

1. A method of manufacturing a semiconductor device, the method comprising:
depositing graphene on a monocrystalline semiconductor substrate, the graphene having an opening exposing the monocrystalline semiconductor substrate through the graphene; and
growing a given monocrystalline semiconductor material from the monocrystalline semiconductor substrate through the opening, said growing including the given monocrystalline semiconductor material outgrowing the opening and covering the graphene thereby forming a monocrystalline semiconductor layer on the graphene.

2. The method of claim 1 wherein said semiconductor device has a monocrystalline structure extending between the monocrystalline semiconductor substrate and the monocrystalline semiconductor layer across the opening.

3. The method of claim 1 wherein said monocrystalline semiconductor substrate is made of a non-polar monocrystalline semiconductor material.

4. The method of claim 3 wherein the non-polar monocrystalline semiconductor material consists of one of: monocrystalline germanium and monocrystalline silicon.

5. The method of claim 1 wherein the monocrystalline semiconductor substrate is made of the given monocrystalline semiconductor material.

6. The method of claim 1 wherein the given monocrystalline semiconductor material is a first monocrystalline semiconductor material, the monocrystalline semiconductor substrate made of a second monocrystalline semiconductor material different from the first monocrystalline semiconductor material.

7. The method of claim 6 wherein the first monocrystalline semiconductor material has a first crystalline lattice parameter matching a second crystalline lattice parameter of the second monocrystalline semiconductor material.

8. The method of claim 1 wherein the opening has an in-plane dimension corresponding to one or more missing carbon atoms.

9. The method of claim 1 wherein the opening has an in-plane dimension of at least 0.5 nm, preferably at least 1 nm and most preferably at least 5 nm.

10. The method of claim 1 wherein said opening has a plurality of openings at a corresponding plurality of spaced-apart locations of said graphene, said growing including growing the given monocrystalline semiconductor material from the monocrystalline semiconductor substrate through the plurality of openings at the plurality of spaced apart locations.

11. The method of claim 10 wherein the plurality of openings has at least ten openings per unit of area, preferably more than a hundred openings per unit of area, and most preferably more than a thousand openings per unit of area.

12. The method of claim 1 wherein said depositing includes depositing a graphene layer on the monocrystalline semiconductor substrate, and removing a given portion of the graphene layer to form the opening.

13. The method of claim 12 wherein said removing includes projecting a plasma beam at a location of the given portion of the graphene layer, the plasma beam carrying an intensity value exceeding an opening forming intensity threshold.

14. The method of claim 13 wherein the plasma beam is an oxygen-plasma beam.

15. The method of claim 1 wherein said depositing includes depositing graphene on a given portion of the monocrystalline semiconductor substrate, a remaining portion of the monocrystalline semiconductor substrate corresponding to the opening.

16. The method of claim 15 wherein said depositing includes positioning a growth mask onto the given portion of the monocrystalline semiconductor substrate, performing said depositing the graphene, and removing the growth mask thereby revealing the opening.

17. The method of claim 1 further comprising detaching the monocrystalline semiconductor layer from the monocrystalline semiconductor substrate.

18. A semiconductor device comprising:
a monocrystalline semiconductor substrate;
a graphene layer covering the monocrystalline semiconductor substrate, the graphene layer having an opening exposing the monocrystalline semiconductor substrate through the graphene layer; and
a monocrystalline semiconductor layer having a first base portion anchoring to the monocrystalline semiconductor substrate via the opening, and a second sheet portion connected to the first base portion and covering the graphene layer.

19. The semiconductor device of claim 18 wherein said semiconductor device has a monocrystalline structure extending between the monocrystalline semiconductor substrate and the monocrystalline semiconductor layer across the opening.

20. The semiconductor device of claim 18 wherein said monocrystalline semiconductor substrate is made of a non-polar monocrystalline semiconductor material.
